(19) United States
(12) Patent Application Publication
(10) Pub. No.: US 2025/0259861 A1
(43) Pub. Date: Aug. 14, 2025

(54) PROCESSING LIQUID SUPPLY SYSTEM, PROCESSING LIQUID SUPPLY METHOD, AND RECORDING MEDIUM

(71) Applicant: Tokyo Electron Limited, Tokyo (JP)

(72) Inventors: Hisashi MORITA, Koshi City (JP); Yuji KIMURA, Koshi City (JP); Yusuke YAMAMOTO, Koshi City (JP); Takashi NAGAI, Koshi City (JP)

(73) Assignee: Tokyo Electron Limited, Tokyo (JP)

(21) Appl. No.: 19/048,047

(22) Filed: Feb. 7, 2025

(30) Foreign Application Priority Data
Feb. 8, 2024 (JP) 2024-017893

(51) Int. Cl. H01L 21/67; G01F 1/34

(52) U.S. Cl. CPC H01L 21/67017; H01L 21/67248; H01L 21/67253; G01F 1/34

(57) ABSTRACT

A processing liquid supply system includes a processing liquid supply path, a pump, a pressure gauge and a flowmeter, and a controller. Through the processing liquid supply path, a processing liquid is supplied to a substrate processing device configured to process a substrate. The pump is provided in the processing liquid supply path. The pressure gauge and the flowmeter are provided downstream of the pump in the processing liquid supply path. The controller controls individual components. The controller detects abnormality in supply of the processing liquid based on a measurement value of the pressure gauge and a measurement value of the flowmeter.

### CROSS-REFERENCE TO RELATED APPLICATION

This application claims the benefit of Japanese Patent Application No. 2024-017893 filed on Feb. 8, 2024, the entire disclosures of which are incorporated herein by reference.

### TECHNICAL FIELD

The various aspects and embodiments described herein pertain generally to a processing liquid supply system, a processing liquid supply method, and a recording medium.

### BACKGROUND

Conventionally, there is known a substrate processing apparatus configured to circulate a processing liquid through a processing tub for processing a substrate to perform various types of processes on the substrate immersed in the processing tub (see Patent Document 1).
Patent Document 1: Japanese Patent Laid-open Publication No. 2021-022707

### SUMMARY

In one or more embodiments of the present application, a processing liquid supply system includes a processing liquid supply path, a pump, a pressure gauge and a flowmeter, and a controller. Through the processing liquid supply path, a processing liquid is supplied to a substrate processing device configured to process a substrate. The pump is provided in the processing liquid supply path. The pressure gauge and the flowmeter are provided downstream of the pump in the processing liquid supply path. The controller controls individual components. The controller detects abnormality in supply of the processing liquid based on a measurement value of the pressure gauge and a measurement value of the flowmeter.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a block diagram illustrating a configuration example of a substrate processing apparatus according to one or more embodiments of the present application;

FIG. 2 is a diagram illustrating a configuration example of a liquid processing device according to one or more embodiments of the present application;

FIG. 3 is a diagram illustrating a configuration example of a processing liquid supply system according to one or more embodiments of the present application;

FIG. 4 is a timing chart illustrating an example sequence of a startup processing performed by the substrate processing apparatus according to one or more embodiments of the present application;

FIG. 5 is a timing chart illustrating an example sequence of a detection processing performed by the processing liquid supply system according to one or more embodiments of the present application;

FIG. 6 is a timing chart illustrating an example sequence of the detection processing performed by the processing liquid supply system according to one or more embodiments of the present application;

FIG. 7 is a diagram illustrating an example of a monitoring table for use in the detection processing performed by the processing liquid supply system according to the exemplary embodiment;

FIG. 8 is a diagram illustrating a configuration example of a processing liquid supply system according to a first modification example of one or more embodiments of the present application;

FIG. 9 is a diagram illustrating a configuration example of a processing liquid supply system according to a second modification example of one or more embodiments of the present application;

FIG. 10 is a block diagram illustrating a configuration example of a liquid processing device according to a third modification example of one or more embodiments of the present application;

FIG. 11 is a diagram illustrating a configuration example of the processing liquid supply system according to the third modification example of one or more embodiments of the present application;

FIG. 12 is a flowchart illustrating an example sequence of a control processing performed by the processing liquid supply system according to one or more embodiments of the present application; and

FIG. 13 is a flowchart illustrating an example sequence of a control processing performed by the processing liquid supply system according to one or more embodiments of the present application.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, one or more embodiments of the present application of a processing liquid supply system, a processing liquid supply method, and a recording medium according to the present disclosure will be described in detail with reference to the accompanying drawings. However, the present disclosure is not limited by the one or more embodiments to be described below. Also, it should be noted that the drawings are schematic and relations in sizes of individual components and ratios of the individual components may sometimes be different from actual values. Even between the drawings, there may exist parts having different dimensional relationships or different ratios.

Conventionally, there is known a substrate processing apparatus in which a processing liquid is circulated through a processing tub for processing a substrate to perform various types of processes on the substrate immersed in the processing tub. In this technique, a flow rate feedback control is performed to control an output of a pump based on a flow rate measured by a flowmeter, for example. This makes it possible to stably supply the processing liquid to a substrate processing device such as the processing tub at a required flow rate.

Meanwhile, if bubbles are formed in a processing liquid supply path for supplying the processing liquid and if these bubbles adhere to the flowmeter, a measurement value of the flowmeter may differ from an actual flow rate. In this way, when abnormality in the supply of the processing liquid occurs in the processing liquid supply path, this abnormality cannot be detected in the aforementioned conventional technique, so there is a risk that a control such as the flow rate feedback control cannot be performed appropriately.

To overcome the aforementioned problem, there is a demand for a technique capable of detecting the supply abnormality in the processing liquid supply path.

### <Configuration of Substrate Processing Apparatus>

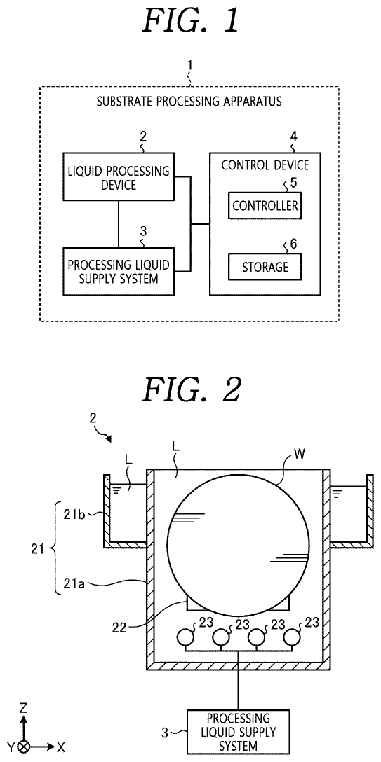

First, a configuration of a substrate processing apparatus 1 including a processing liquid supply system 3 according to the present disclosure will be explained with reference to FIG. 1. FIG. 1 is a block diagram illustrating a configuration example of the substrate processing apparatus 1 according to an exemplary embodiment.

As shown in FIG. 1, the substrate processing apparatus 1 according to one or more embodiments of the present application is equipped with a liquid processing device 2, a processing liquid supply system 3, and a control device 4. The liquid processing device 2 is an example of a substrate processing device.

The liquid processing device 2 is configured to process a substrate (hereinafter, also referred to as “wafer”) such as a semiconductor wafer by using a processing liquid L (see FIG. 2).

The processing liquid L according to the exemplary embodiment contains, by way of example, a phosphoric acid (H₃PO₄) aqueous solution. In the present disclosure, the phosphoric acid aqueous solution is also simply referred to as “phosphoric acid”. Further, the processing liquid L according to the exemplary embodiment may also include a silicic acid compound. This silicic acid compound can be added to the phosphoric acid aqueous solution, for example, with a solution in which colloidal silicon is dispersed.

In addition, in the present disclosure, the processing liquid L is not limited to the one containing the phosphoric acid, and any of various types of processing liquids for liquid-processing the wafer W may be employed.

The processing liquid supply system 3 is configured to supply the above-described processing liquid L to the liquid processing device 2. A configuration example of the processing liquid supply system 3 will be described later.

The control device 4 controls the liquid processing device 2 and the processing liquid supply system 3. The control device 4 is, for example, a computer, and includes a controller 5 and a storage 6. The storage 6 stores therein programs for controlling various types of processes performed in the substrate processing apparatus 1. The controller 5 controls operations of the liquid processing device 2 and the processing liquid supply system 3 by reading and executing the programs stored in the storage 6. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

Further, these programs may be recorded on a computer-readable recording medium and installed from the recording medium into the storage 6 of the control device 4. The computer-readable recording medium may be, by way of non-limiting example, a hard disk (HD), a flexible disk (FD), a compact disk (CD), a magnet optical disk (MO), a memory card, or the like.

The substrate processing apparatus 1 may be equipped with a plurality of liquid processing devices 2. In this case, the substrate processing apparatus 1 may include a plurality of processing liquid supply systems 3 respectively corresponding to the plurality of liquid processing devices 2, or may include one processing liquid supply system 3 corresponding to all the plurality of liquid processing devices 2.

### <Configuration of Liquid Processing Device>

Now, a configuration example of the liquid processing device 2 will be described with reference to FIG. 2. FIG. 2 is a diagram illustrating an example of the configuration of the liquid processing device 2 according to one or more embodiments of the present application.

The liquid processing device 2 shown in FIG. 2 is a batch type processing device configured to process a multiple number of wafers W (only one is shown in FIG. 2) all at once. As depicted in FIG. 2, the liquid processing device 2 is equipped with a processing tub 21, a holder 22, and a plurality of (here, four) dischargers 23. Here, the number of the dischargers 23 included in the liquid processing device 2 is not limited to four.

The processing tub 21 includes an inner tub 21a and an outer tub 21b. The inner tub 21a is a box-shaped tub with an open top, and stores the processing liquid L therein. A lot composed of a plurality of wafers W is immersed in the inner tub 21a. The outer tub 21b is disposed around the inner tub 21a. The outer tub 21b also has an open top. The processing liquid L that has overflown from the inner tub 21a is introduced into the outer tub 21b.

The holder 22 is configured to hold the multiple number of wafers W forming the lot in a vertical posture. The holder 22 has an elevating mechanism (not shown) configured to move the wafers W held thereby up and down, and serves to lower the lot from above the inner tub 21a in the processing tub 21 to immerse it in the inner tub 21a, or raise the lot immersed in the inner tub 21a to take it out from the processing tub 21.

The plurality of dischargers 23 are disposed inside the inner tub 21a, specifically, in the vicinity of a bottom of the inner tub 21a. The dischargers 23 are connected to the processing liquid supply system 3, and discharge the processing liquid L supplied from the processing liquid supply system 3 into the inner tub 21a.

The liquid processing device 2 holds the lot with the holder 22, and immerses the lot held thereby in the processing liquid L stored in the inner tub 21a. As a result, the multiple number of wafers W are processed by the processing liquid L.

For example, in one or more embodiments of the present application, among a silicon nitride film and a silicon oxide film formed on the wafer W, the silicon nitride film is selectively etched by the phosphoric acid aqueous solution, which is the processing liquid L.

### <Configuration of Processing Liquid Supply System>

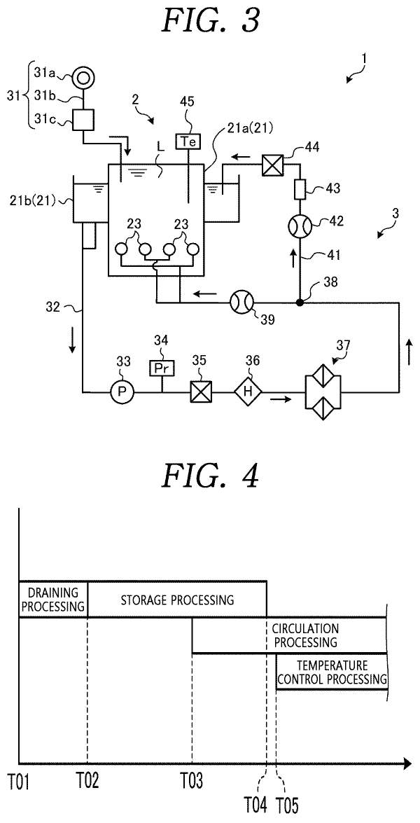

Now, a configuration example of the processing liquid supply system 3 will be described with reference to FIG. 3. FIG. 3 is a diagram illustrating a configuration example of the processing liquid supply system 3 according to one or more embodiments of the present application.

As depicted in FIG. 3, the processing liquid supply system 3 includes a processing liquid supply 31 and a circulation path 32. The circulation path 32 is an example of a processing liquid supply path. The processing liquid supply 31 supplies the processing liquid L to the processing tub 21. The processing liquid supply 31 supplies unused processing liquid L to the inner tub 21a of the processing tub 21, for example.

The processing liquid supply 31 has a source 31a, a supply path 31b, and a flow rate controller 31c. The source 31a is, for example, a tank that stores the processing liquid L therein. The supply path 31b connects the source 31a to the inner tub 21a, allowing the processing liquid L to be supplied from the source 31a to the inner tub 21a. Also, the supply path 31b may be connected to the outer tub 21b.

The flow rate controller 31c is provided in the supply path 31b, and serves to adjust the amount of the processing liquid L supplied to the processing tub 21. The flow rate controller 31c is composed of, by way of example, an opening/closing valve, a flow control valve, a flowmeter, and so forth.

The circulation path 32 is connected to the liquid processing device 2 to supply the processing liquid L to the liquid processing device 2. The circulation path 32 is a circulation line through which the processing liquid L flowing out from the processing tub 21 is returned back into the processing tub 21.

Specifically, one end of the circulation path 32 is connected to multiple positions (two positions in FIG. 3) at a bottom of the outer tub 21b, and the other end of the circulation path 32 is connected to the plurality of dischargers 23 located inside the inner tub 21a. In the processing liquid supply system 3, the processing liquid L sent from the outer tub 21b into the circulation path 32 passes through the circulation path 32 and is then supplied from the dischargers 23 into the inner tub 21a.

Furthermore, the processing liquid L supplied from the dischargers 23 into the inner tub 21a overflows from the inner tub 21a into the outer tub 21b. In this way, the circulation path 32 allows the processing liquid L to be circulated between the inner tub 21a and the outer tub 21b.

The circulation path 32 is provided with a pump 33, a pressure gauge 34, a check valve 35, a heater 36, a filter 37, a branching portion 38, and a flowmeter 39 in this order from the upstream side with respect to the processing tub 21.

The pump 33 forms a circulating flow of the processing liquid L that comes out from the processing tub 21, passes through the circulation path 32, and returns back into the processing tub 21. The pump 33 is, by way of non-limiting example, a magnetic levitation pump configured to force-feed the processing liquid L as a rotator thereof is rotated in the processing liquid L while being magnetically levitated. However, the pump 33 of the present disclosure is not limited to the magnetic levitation pump, and may be, by way of example, a diaphragm pump or the like.

Meanwhile, since the magnetic levitation pump, which has higher liquid feeding capacity than other types of pumps, is used for the pump 33, the feed flow rate of the processing liquid L returned from the circulation path 32 into the processing tub 21 can be increased.

The pressure gauge 34 measures the pressure of the processing liquid L flowing through the circulation path 32. A measurement value of the pressure of the processing liquid L measured by the pressure gauge 34 is outputted to the controller 5 (see FIG. 1). The check valve 35 suppresses a backflow of the processing liquid L flowing through the circulation path 32. The check valve 35 is, by way of non-limiting example, an air-operated valve.

The heater 36 heats the processing liquid L flowing through the circulation path 32. In this exemplary embodiment, by heating the processing liquid L with this heater 36, the processing liquid L stored in the processing tub 21 is heated up to a processing temperature (for example, about 160° C. to 170° C.) required for processing the wafer W.

The filter 37 is configured to remove contaminants such as particles contained in the processing liquid L flowing through the circulation path 32. The filter 37 may include a plurality of filter modules arranged in parallel.

The number of the filter modules belonging to the single filter 37 may be decided in consideration of filtration ability required for the filter 37, a pressure drop allowed in the filter 37, and so forth. In the present disclosure, the filter 37 is composed of two filter modules arranged in parallel, as illustrated in FIG. 3.

A branch path 41 leading to the outer tub 21b of the processing tub 21 is branched off from the branching portion 38. The flowmeter 39 measures the flow rate of the processing liquid L flowing through the circulation path 32. A measurement value of the flow rate of the processing liquid L measured by the flowmeter 39 is outputted to the controller 5.

The branch path 41 is a flow path for sampling the concentration of the processing liquid L flowing through the circulation path 32. A flowmeter 42, a concentration meter 43, and a valve 44 are provided in this branch path 41 in this order from the upstream side with respect to the branching portion 38.

The flowmeter 42 measures the flow rate of the processing liquid L flowing through the branch path 41. A measurement value of the flow rate of the processing liquid L measured by the flowmeter 42 is outputted to the controller 5.

The concentration meter 43 measures the concentration of the processing liquid L flowing through the branch path 41, which reflects the concentration of the processing liquid Lflowing through the circulation path 32. The concentration meter 43 measures, for example, a phosphoric acid concentration of the processing liquid L flowing through the branch path 41. A measurement value of the concentration of the processing liquid L measured by the concentration meter 43 is outputted to the controller 5. The valve 44 controls whether or not the processing liquid L is to be supplied from the branching portion 38 to the outer tub 21b.

The processing liquid supply system 3 is also equipped with a thermometer 45. The thermometer 45 measures the temperature of the processing liquid L flowing through the circulation path 32 by measuring the temperature of the processing liquid L stored in the processing tub 21. The thermometer 45 measures the temperature of the processing liquid L stored in the inner tub 21a, for example. A measurement value of the temperature of the processing liquid L measured by the thermometer 45 is outputted to the controller 5.

Furthermore, the thermometer 45 of the present disclosure is not limited to measuring the temperature of the processing liquid L stored in the inner tub 21a, but may be configured to measure the temperature of the processing liquid L stored in the outer tub 21b or to measure the temperature of the processing liquid L flowing through the circulation path 32.

### <Startup Process>

Now, an outline of a startup processing of the substrate processing apparatus 1 according to one or more embodiments of the present application will be described with reference to FIG. 4. FIG. 4 is a timing chart showing an example sequence of the startup processing performed by the substrate processing apparatus 1 according to the embodiment.

First, the controller 5 (see FIG. 1) performs a draining processing of draining all the processing liquid L used (see FIG. 3) from the inner tub 21a (see FIG. 3) and the outer tub 21b (see FIG. 3) of the processing tub 21 (see FIG. 3) from time T01.

Next, from time T02 when the draining processing is completed, the controller 5 performs a storage processing of replenishing the inner tub 21a and the outer tub 21b of the processing tub 21 with the processing liquid L unused. Specifically, the controller 5 first supplies the processing liquid L from the processing liquid supply 31 (see FIG. 3) to the inner tub 21a, filling the inner tub 21a with the processing liquid L.

Next, the controller 5 further supplies the processing liquid L from the processing liquid supply 31 into the inner tub 21a, thus allowing the processing liquid L overflowing from the inner tub 21a to be supplied into the outer tub 21b. Then, at time T04 when the liquid level of the processing liquid L supplied to the outer tub 21b reaches a predetermined second height, the controller 5 ends the storage processing.

The controller 5 performs a circulation processing of circulating the processing liquid L through the circulation path 32 (see FIG. 3) from time T03 when the liquid level of the processing liquid L supplied into the outer tub 21b reaches a preset first height, which is lower than the second height. During this circulation processing, from time T05 when the processing liquid L meets a condition to be described below, the controller 5 performs a temperature control processing of adjusting the temperature of the processing liquid L to a preset processing temperature.

### <Details of Detection Processing>

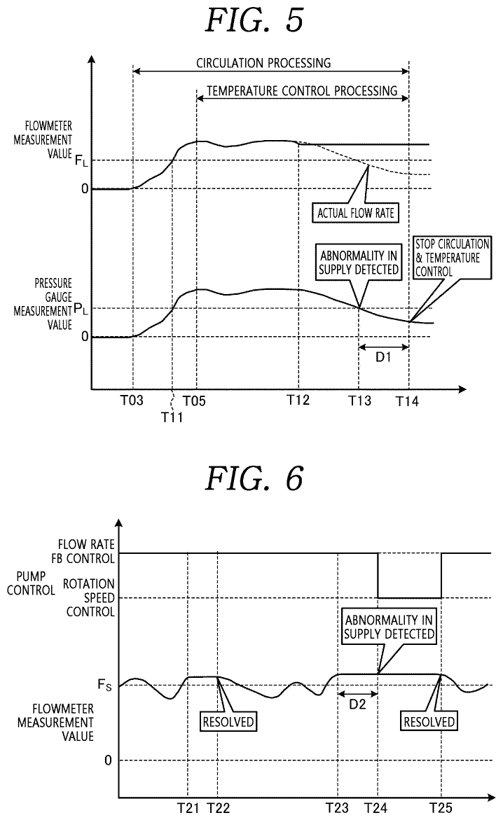

Now, details of a detection processing of detecting abnormality in the supply of the processing liquid L in the processing liquid supply system 3 according to one or more embodiments of the present application will be described with reference to FIG. 5 to FIG. 7. FIG. 5 is a timing chart illustrating an example sequence of the detection processing performed by the processing liquid supply system 3 according to one or more embodiments of the present application.

As shown in FIG. 5, the controller 5 (see FIG. 1) operates the pump 33 (see FIG. 3) from the aforementioned time T03 to allow the processing liquid L (see FIG. 3) to flow through the circulation path 32 (see FIG. 3), thereby performing a circulation processing in which the processing liquid L is circulated through the circulation path 32.

In addition, when a magnetic levitation pump is used for the pump 33, there are two types of operation modes for the pump 33: a flow rate feedback control (referred to as “flow rate FB control” in the accompanying drawings) and a rotation speed control.

In flow rate feedback control, the rotation speed of the rotator inside the pump 33 is automatically controlled so that a flow rate measurement value of the processing liquid L measured by the flowmeter 39 (see FIG. 3) reaches a designated flow rate.

By way of example, in the flow rate feedback control, if the flow rate measurement value of the processing liquid L is lower than the designated flow rate, the pump 33 increases the rotation speed of the rotator. On the other hand, in the flow rate feedback control, if the flow rate measurement value of the processing liquid L is higher than the designated flow rate, the pump 33 reduces the rotation speed of the rotator.

In the rotation speed control, the rotation speed of the rotator of the pump 33 is controlled to a specified rotation speed.

In the circulation processing according to one or more embodiments of the present application, the controller 5 operates the pump 33 with the flow rate feedback control. Furthermore, in this circulation processing, the controller 5 operates the pump 33, while setting the flow rate of the processing liquid L in the circulation path 32 to a predetermined flow rate. As a result, the measurement value of the flowmeter 39 gradually rises from zero, as shown in FIG. 5.

Next, in the present exemplary embodiment, from the time T05 after the start of the circulation processing, the controller 5 operates the heater 36 (see FIG. 3) to perform a temperature control processing for the processing liquid L. Here, the time T05 is a time upon the lapse of a predetermined time period from time T11 at which the measurement value of the flowmeter 39 reaches a minimum circulation flow rate F_{L}.

In this way, by allowing a margin of a certain period of time before operating the heater 36 instead of operating the heater 36 immediately after the minimum circulation flow rate F_{L}is reached, it is possible to operate the heater 36 after ensuring a sufficient circulation flow rate in the circulation path 32.

Therefore, according to one or more embodiments of the present application, it is possible to suppress problems that might be caused by operating the heater 36 in a situation where the flow rate in the circulation path 32 is not enough.

In the present exemplary embodiment, from time T12 later than the time T05, there occurs a phenomenon in which the measurement value obtained by the flowmeter 39 does not fluctuate but remains constant (hereinafter, also referred to as “flowmeter hold phenomenon”). This flowmeter hold phenomenon takes place as a result of bubbles generated in the processing liquid L adhering to the flowmeter 39, for example.

In the example of FIG. 5, an actual flow rate of the processing liquid L indicated by a dashed line gradually decreases from the time T12. Since, however, there is no change in the measurement value of the flowmeter 39, the pump 33 performs the flow rate feedback control so as not to change the rotation speed of the rotator.

Since the rotation speed of the rotator of the pump 33 does not fluctuate, a measurement value of the pressure gauge 34 (see FIG. 3) provided in the circulation path 32 also gradually decreases from the time T12.

Here, in one or more embodiments of the present application, the controller 5 detects the abnormal supply of the processing liquid L based on the measurement value of the pressure gauge 34 and the measurement value of the flowmeter 39. By way of example, in the example of FIG. 5, when there is no change in the measurement value of the flowmeter 39 and the measurement value of the pressure gauge 34 becomes equal to or lower than a predetermined lower limit pressure P_{L} (time T13 in the example of FIG. 5), the controller 5 detects the abnormality in the supply of the processing liquid L.

This makes it possible to detect abnormality in the supply of the processing liquid L even when the flowmeter 39 is not outputting an appropriate measurement value due to bubbles adhering thereto, or the like.

Furthermore, in one or more embodiments of the present application, the circulation processing and the temperature control processing are continued even after the time T13 when the abnormality in the supply of the processing liquid L is detected. Accordingly, if the flowmeter 39 resumes outputting an appropriate measurement value after the time T13 due to removal of the bubbles or the like adhering thereto, the circulation processing and the temperature control processing can be carried on.

In the present exemplary embodiment, however, even at time T14 upon the lapse of a preset time period D1 from the time T13, the measurement value of the flowmeter 39 does not change, and the measurement value of the pressure gauge 34 is still found to be below the lower limit pressure P_{L}.

In this case, the controller 5 makes a determination that the flowmeter 39 is unlikely to resume the output of an appropriate measurement value, so the controller 5 stops the operations of the pump 33 and the heater 36, thereby stopping the circulation processing and the temperature control processing. This makes it possible to suppress damage to the processing liquid supply system 3 and the liquid processing device 2 due to the abnormality in the supply of the processing liquid L.

FIG. 6 is a timing chart showing an example sequence of the detection processing performed by the processing liquid supply system 3 according to one or more embodiments of the present application. FIG. 6 shows an example where the startup processing of the substrate processing apparatus 1 (see FIG. 1) is completed and the processing liquid L (see FIG. 3) is flowing through the circulation path 32 (see FIG. 3) at a processing flow rate Fₛ for processing the wafer W (see FIG. 2).

In this case, the controller 5 (see FIG. 1) operates the pump 33 (see FIG. 3) by setting the operation mode of the pump 33 to be the flow rate feedback control, as illustrated in FIG. 6. Furthermore, in this flow rate feedback control, the flow rate of the processing liquid L in the circulation path 32 is set to the processing flow rate Fₛ. This allows the controller 5 to stably supply the processing liquid L to the liquid processing device 2 at the processing flow rate Fₛ.

In the example of FIG. 6, the flowmeter hold phenomenon occurs at time T21. In this case, the controller 5 maintains the control over the pump 33 in the flow rate feedback control mode from this time T21 until a predetermined time period D2 (e.g., about 5 seconds) elapses.

In this way, by maintaining the flow rate feedback control during the time period D2, when the flowmeter 39 resumes outputting an appropriate measurement value after the time T21 due to elimination of the bubbles or the like, the feeding of the processing liquid L from the processing liquid supply system 3 can be continued.

In the example of FIG. 6, since the flowmeter hold phenomenon has been resolved at time T22 before the lapse of the predetermined time period D2 from the time T21, the controller 5 is continuing to operate the pump 33 even after the time T22, under the flow rate feedback control in which the set flow rate is set to the processing flow rate Fₛ.

In the example of FIG. 6, the flowmeter hold phenomenon occurs again at time T23 later than the time T22. In this case, the same as described above, the controller 5 maintains the control over the pump 33 in the flow rate feedback control mode from this time T23 until the predetermined time period D2 passes by.

Also, in the example of FIG. 6, the flowmeter hold phenomenon lasts even at time T24 upon the lapse of the predetermined time period D2 from the time T23. In this case, the controller 5 detects abnormality in the supply of the processing liquid L.

Thus, even when the flowmeter 39 is not outputting an appropriate measurement value due to bubbles adhering thereto or the like, the abnormality in the supply of the processing liquid L may be detected.

Then, as depicted in FIG. 6, at the time T24 when the abnormality in the supply of the processing liquid L is detected, the controller 5 switches the operation mode of the pump 33 from the flow rate feedback control to the rotation speed control.

In this case, the controller 5 calculates a rotation speed R1 at which the pump 33 is capable of feeding the processing liquid L at the processing flow rate Fₛ from the following expression (1), and operates the pump 33 at this rotation speed R1.

R1(rpm)=Fₛ(L/min)×B (1)

The parameter B included in the expression (1) is a rotational speed (rpm/L) of the pump 33 for feeding 1L of the processing liquid L per minute, and this value is determined individually based on the liquid feeding capacity of the pump 33.

In this way, by switching the operation mode of the pump 33 to the rotation speed control, it is possible to circulate the processing liquid L at a flow rate close to the processing flow rate Fₛ even in the event of the flowmeter hold phenomenon in which the flow rate feedback control cannot be performed appropriately.

Therefore, according to the present exemplary embodiment, even if the flowmeter 39 does not output a proper measurement value due to, for example, adhesion of bubbles thereto, the processing liquid L can still be fed.

Further, in the example of FIG. 6, the flowmeter hold phenomenon is resolved at time T25, which is later than the time T24. In this case, the controller 5 switches the operation mode of the pump 33 from the rotation speed control to the flow rate feedback control at the time T25 when the flowmeter hold phenomenon is resolved. In this flow rate feedback control, the flow rate of the processing liquid L in the circulation path 32 is set to the processing flow rate Fₛ.

Accordingly, when the flowmeter 39 is operating normally, the flow rate of the processing liquid L in the circulation path 32 can be accurately maintained at the processing flow rate Fₛ.

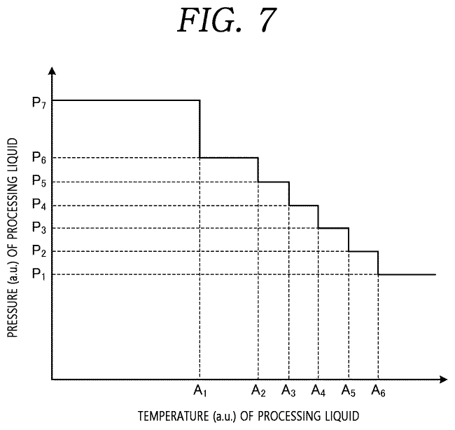

FIG. 7 illustrates an example of a monitoring table used in the detection processing performed by the processing liquid supply system 3 according to one or more embodiments of the present application. In one or more embodiments of the present application, the storage 6 (see FIG. 1) stores the monitoring table of FIG. 7 in which a pressure threshold according to the temperature of the processing liquid L is set.

The controller 5 (see FIG. 1) detects abnormality in the supply of the processing liquid L when a measurement value of the pressure gauge 34 exceeds the pressure threshold according to the temperature of the processing liquid L set in the monitoring table stored in the storage 6.

By way of example, in the example of FIG. 7, when the temperature of the processing liquid L is less than a temperature A₁, the pressure threshold is P₇. Then, when the measurement value of the thermometer 45 becomes less than the temperature A₁ and the measurement value of the pressure gauge 34 exceeds a pressure P₇, the controller 5 detects abnormality in the supply of the processing liquid L and immediately stops the operations of the pump 33 and the heater 36.

This makes it possible to suppress damage to the processing liquid supply system 3 and the liquid processing device 2 that might be caused by the abnormality in the supply of the processing liquid L.

Further, in the example of FIG. 7, when the temperature of the processing liquid L is equal to or higher than the temperature A₁ and less than a temperature A₂, the pressure threshold is a pressure P₆. Then, when the measurement value of the thermometer 45 becomes equal to or higher than the temperature A₁ and less than the temperature A₂, and the measurement value of the pressure gauge 34 exceeds the pressure P₆, the controller 5 detects abnormality in the supply of the processing liquid L and immediately stops the operations of the pump 33 and the heater 36.

This makes it possible to suppress damage to the processing liquid supply system 3 and the liquid processing device 2 that might be caused by the abnormality in the supply of the processing liquid L.

Also, in the example of FIG. 7, when the temperature of the processing liquid L is equal to or higher than the temperature A₂ and less than a temperature A₃, the pressure threshold is a pressure P₅. Then, when the measurement value of the thermometer 45 becomes equal to or higher than the temperature A₂ and less than the temperature A₃, and the measurement value of the pressure gauge 34 exceeds the pressure P₅, the controller 5 detects abnormality in the supply of the processing liquid L and immediately stops the operations of the pump 33 and the heater 36.

This makes it possible to suppress damage to the processing liquid supply system 3 and the liquid processing device 2 that might be caused by the abnormality in the supply of the processing liquid L.

Furthermore, in the example of FIG. 7, when the temperature of the processing liquid L is equal to or higher than the temperature A₃ and less than a temperature A₄, the pressure threshold is a pressure P₄. Then, when the measurement value of the thermometer 45 becomes equal to or higher than the temperature A₃ and less than the temperature A₄, and the measurement value of the pressure gauge 34 exceeds a pressure P₄, the controller 5 detects abnormality in the supply of the processing liquid L and immediately stops the operations of the pump 33 and the heater 36.

This makes it possible to suppress damage to the processing liquid supply system 3 and the liquid processing device 2 that might be caused by the abnormality in the supply of the processing liquid L.

Also, in the example of FIG. 7, when the temperature of the processing liquid L is equal to or higher than the temperature A₄ and less than a temperature A₅, the pressure threshold is a pressure P₃. Then, when the measurement value of the thermometer 45 becomes equal to or higher than the temperature A₄ and less than the temperature A₅, and the measurement value of the pressure gauge 34 exceeds the pressure P₃, the controller 5 detects abnormality in the supply of the processing liquid L and immediately stops the operations of the pump 33 and the heater 36.

This makes it possible to suppress damage to the processing liquid supply system 3 and the liquid processing device 2 that might be caused by the abnormality in the supply of the processing liquid L.

In the example of FIG. 7, when the temperature of the processing liquid L is equal to or higher than the temperature A₅ and less than a temperature A₆, the pressure threshold is a pressure P2. Then, when the measurement value of the thermometer 45 becomes equal to or higher than the temperature A₅ and less than the temperature A₆, and the measurement value of the pressure gauge 34 exceeds the pressure P₂, the controller 5 detects abnormality in the supply of the processing liquid L and immediately stops the operations of the pump 33 and the heater 36.

This makes it possible to suppress damage to the processing liquid supply system 3 and the liquid processing device 2 that might be caused by the abnormality in the supply of the processing liquid L.

Furthermore, in the example of FIG. 7, when the temperature of the processing liquid L is equal to or higher than the temperature A₆, the pressure threshold is a pressure P₁. Then, when the measurement value of the thermometer 45 becomes equal to or higher than the temperature A₆ and the measurement value of the pressure gauge 34 exceeds the pressure P₁, the controller 5 detects abnormality in the supply of the processing liquid L and immediately stops the operations of the pump 33 and the heater 36.

This makes it possible to suppress damage to the processing liquid supply system 3 and the liquid processing device 2 that might be caused by the abnormality in the supply of the processing liquid L.

In addition, in the monitoring table according to one or more embodiments of the present application, the pressure threshold according to the temperature of the processing liquid L may gradually decrease as the temperature of the processing liquid L increases. With such a rise of the temperature of the processing liquid L, the pressure resistant capacity of the circulation path 32 gradually decreases. However, by setting the monitoring table as described above, it is possible to suppress damage to the processing liquid supply system 3 and the liquid processing device 2 in any temperature range.

Moreover, although FIG. 7 illustrates the example where the pressure threshold changes stepwise in the range of the temperature A₁ to the temperature A₆, the present disclosure is not limited thereto. The pressure threshold may vary linearly, or in a curved shape such as a quadratic curve.

### Various Modification Examples

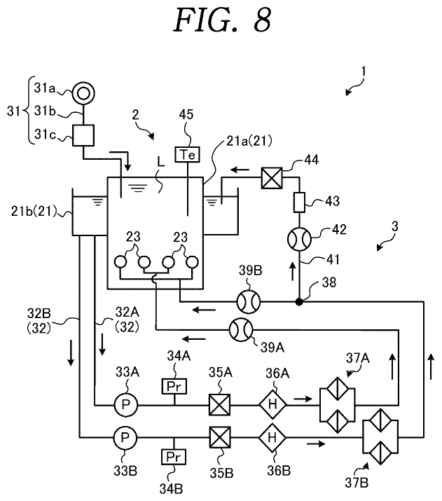

Subsequently, the processing liquid supply system 3 according to various modification examples of one or more embodiments of the present application will be explained with reference to FIG. 8 to FIG. 11. FIG. 8 illustrates a configuration example of the processing liquid supply system 3 according to a first modification example.

In the first modification example shown in FIG. 8, the configuration of the circulation path 32 differs from that of the above-described exemplary embodiment. Specifically, in this first modification example, multiple circulation paths 32 (two in the example of FIG. 8) are provided for the single processing tub 21. With this configuration, it is possible to increase the feed flow rate of the processing liquid L returned back into the processing tub 21 from the circulation path 32, as compared to the case where only one circulation path 32 is provided for the single processing tub 21.

The circulation path 32 according to the first modification example includes circulation paths 32A and 32B. The circulation paths 32A and 32B are an example of a processing liquid supply path. Each of the circulation paths 32A and 32B is connected to the liquid processing device 2 to supply the processing liquid L to the liquid processing device 2. Each of the circulation paths 32A and 32B is a circulation line through which the processing liquid L flows out from the processing tub 21 and back into the processing tub 21.

To elaborate, one end of each of the circulation paths 32A and 32B is connected to the bottom of the outer tub 21b, and the other end of each of the circulation paths 32A and 32B is connected to the plurality of dischargers 23 located inside the inner tub 21a.

In the processing liquid supply system 3, the processing liquid L sent from the outer tub 21b to the circulation paths 32A and 32B passes through the circulation paths 32A and 32B and is then supplied into the inner tub 21a from the dischargers 23.

Furthermore, the processing liquid L supplied from the dischargers 23 to the inner tub 21a overflows from the inner tub 21a into the outer tub 21b. In this way, the circulation paths 32A and 32B circulate the processing liquid L between the inner tub 21a and the outer tub 21b.

The circulation path 32A is provided with a pump 33A, a pressure gauge 34A, a check valve 35A, a heater 36A, a filter 37A, and a flowmeter 39A in this order from the upstream side with respect to the processing tub 21.

The pump 33A forms a circulation flow of the processing liquid L that comes out from the processing tub 21, passes through the circulation path 32A, and then returns back into the processing tub 21. The pump 33A is, for example, a magnetic levitation pump. However, it should be noted that the pump 33A of the present disclosure is not limited to the magnetic levitation pump, and may be a diaphragm pump, or the like.

The pressure gauge 34A measures the pressure of the processing liquid L flowing through the circulation path 32A. A measurement value of the pressure of the processing liquid L measured by the pressure gauge 34A is outputted to the controller 5 (see FIG. 1). The check valve 35A suppresses a backflow of the processing liquid L flowing through the circulation path 32A. The check valve 35A is, by way of non-limiting example, an air-operated valve.

The heater 36A heats the processing liquid L flowing through the circulation path 32A. In the first modification example, by heating the processing liquid L with the heater 36A, the processing liquid L stored in the processing tub 21 is heated up to a processing temperature required for processing the wafer W.

The filter 37A removes contaminants such as particles contained in the processing liquid L flowing through the circulation path 32A. The filter 37A may include multiple filter modules arranged in parallel.

The flowmeter 39A measures the flow rate of the processing liquid L flowing through the circulation path 32A. A measurement value of the flow rate of the processing liquid L measured by the flowmeter 39A is outputted to the controller 5.

The circulation path 32B is provided with a pump 33B, a pressure gauge 34B, a check valve 35B, a heater 36B, a filter 37B, the branching portion 38, and a flowmeter 39B in this order from the upstream side with respect to the processing tub 21.

The pump 33B forms a circulation flow of the processing liquid L that flows out from the processing tub 21, passes through the circulation path 32B, and then returns back into the processing tub 21. The pump 33B is, for example, a magnetic levitation pump configured to force-feed the processing liquid L as a rotator thereof is rotated in the processing liquid L while being magnetically levitated. However, the pump 33B of the present disclosure is not limited to the magnetic levitation pump, and may be a diaphragm pump or the like.

The pressure gauge 34B measures the pressure of the processing liquid L flowing through the circulation path 32B. A measurement value of the pressure of the processing liquid L measured by the pressure gauge 34B is outputted to the controller 5. The check valve 35B suppresses a backflow of the processing liquid L flowing through the circulation path 32B. The check valve 35B is, by way of non-limiting example, an air-operated valve.

The heater 36B heats the processing liquid L flowing through the circulation path 32B. In the first modification example, by heating the processing liquid L with this heater 36B, the processing liquid L stored in the processing tub 21 is heated up to a processing temperature required for processing the wafer W.

The filter 37B removes contaminants such as particles contained in the processing liquid L flowing through the circulation path 32B. The filter 37B may include multiple filter modules arranged in parallel.

The branch path 41 that leads to the outer tub 21b of the processing tub 21 is branched off from the branching portion 38. The flowmeter 39B measures the flow rate of the processing liquid L flowing through the circulation path 32B. A measurement value of the flow rate of the processing liquid L measured by the flowmeter 39B is outputted to the controller 5.

The branch path 41 is a flow path for sampling the concentration of the processing liquid L flowing through the circulation path 32B. This branch path 41 is provided with the flowmeter 42, the concentration meter 43, and the valve 44 in this order from the upstream side with respect to the branching portion 38.

The flowmeter 42 measures the flow rate of the processing liquid L flowing through the branch path 41. A measurement value of the flow rate of the processing liquid L measured by the flowmeter 42 is outputted to the controller 5.

The concentration meter 43 measures the concentration of the processing liquid L flowing through the branch path 41 to measure the concentration of the processing liquid L flowing through the circulation path 32. The concentration meter 43 measures, for example, a phosphoric acid concentration of the processing liquid L flowing through the branch path 41. A measurement value of the concentration of the processing liquid L measured by the concentration meter 43 is outputted to the controller 5. The valve 44 controls whether or not the processing liquid L is to be supplied from the branching portion 38 to the outer tub 21b.

In the processing liquid supply system 3 of the first modification example described so far, by performing the same detection processing as in the above-described exemplary embodiment, abnormality in the supply of the processing liquid L in the circulation paths 32A and 32B can be detected.

In the example of FIG. 8 described so far, the circulation path 32 includes the two circulation paths 32A and 32B. However, the present disclosure is not limited thereto, and the circulation path 32 may include three or more circulation paths.

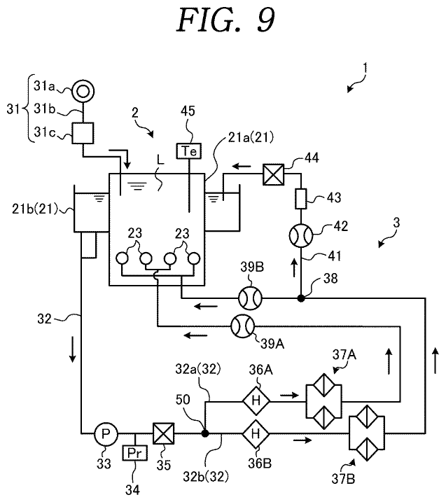

FIG. 9 illustrates a configuration example of the processing liquid supply system 3 according to a second modification example. The second modification example shown in FIG. 9 is different from one or more embodiments of the present application and the first modification example described above in the configuration of the circulation path 32.

Specifically, in this second modification example, the single circulation path 32 is branched at a branching portion 50 thereof into multiple (two in the shown example) branch circulation paths 32a and 32b. The branch circulation paths 32a and 32b are an example of a processing liquid supply path.

With this configuration, the feed flow rate of the processing liquid L returned from the circulation path 32 back into the processing tub 21 can be increased, as compared to the case where the single circulation path 32 is provided from the uppermost stream to the downmost stream for the single processing tub 21.

The circulation path 32 is provided with the pump 33, the pressure gauge 34, the check valve 35, and the branching portion 50 in this order from the upstream side with respect to the processing tub 21. Also, the circulation path 32 is branched into the branch circulation paths 32a and 32b at the branching portion 50.

The pump 33 forms a circulation flow of the processing liquid L that flows out from the processing tub 21, passes through the circulation path 32 and the branch circulation paths 32a and 32b, and returns back into the processing tub 21. The pump 33 is, by way of non-limiting example, a magnetic levitation pump. However, the pump 33 of the present disclosure is not limited to the magnetic levitation pump, and may be a diaphragm pump or the like.

The pressure gauge 34 measures the pressure of the processing liquid L flowing through the circulation path 32. A measurement value of the pressure of the processing liquid L measured by the pressure gauge 34 is outputted to the controller 5 (see FIG. 1). The check valve 35 suppresses a backflow of the processing liquid L flowing through the circulation path 32. The check valve 35 is, for example, an air-operated valve.

In this way, by disposing the pump 33 upstream of the branching portion 50, the processing liquid L can be sent to the multiple branch circulation paths 32a and 32b without needing to increase the number of the pump 33. Therefore, according to the second modification example, the manufacturing cost of the processing liquid supply system 3 can be reduced.

The branch circulation path 32a is provided with a heater 36A, a filter 37A, and a flowmeter 39A in this order from the upstream side with respect to the branching portion 50.

The heater 36A heats the processing liquid L flowing through the branch circulation path 32a. In the second modification example, by heating the processing liquid L with this heater 36A, the processing liquid L stored in the processing tub 21 is heated up to a processing temperature required for processing the wafer W.

The filter 37A removes contaminants such as particles contained in the processing liquid L flowing through the branch circulation path 32a. The filter 37A may include multiple filter modules arranged in parallel.

The flowmeter 39A measures the flow rate of the processing liquid L flowing through the branch circulation path 32a. A measurement value of the flow rate of the processing liquid L measured by the flowmeter 39A is outputted to the controller 5.

The branch circulation path 32b is provided with a heater 36B, a filter 37B, a branching portion 38, and a flowmeter 39B in this order from the upstream side with respect to the branching portion 50.

The heater 36B heats the processing liquid L flowing through the branch circulation path 32b. In the second modification example, by heating the processing liquid L with this heater 36B, the processing liquid L stored in the processing tub 21 is heated up to the processing temperature required for processing the wafer W.

The filter 37B removes contaminants such as particles contained in the processing liquid L flowing through the branch circulation path 32b. The filter 37B may include multiple filter modules arranged in parallel.

The branch path 41 leading to the outer tub 21b of the processing tub 21 is branched from the branching portion 38. The flowmeter 39B measures the flow rate of the processing liquid L flowing through the branch circulation path 32b. A measurement value of the flow rate of the processing liquid L measured by the flowmeter 39B is outputted to the controller 5.

The branch path 41 is a flow path for sampling the concentration of the processing liquid L flowing through the branch circulation path 32b. This branch path 41 is provided with the flowmeter 42, the concentration meter 43, and the valve 44a in this order from the upstream side with respect to the branching portion 38.

The flowmeter 42 measures the flow rate of the processing liquid L flowing through the branch path 41. A measurement value of the flow rate of the processing liquid L measured by the flowmeter 42 is outputted to the controller 5.

The concentration meter 43 measures the concentration of the processing liquid L flowing through the branch path 41 to measure the concentration of the processing liquid L flowing through the circulation path 32. The concentration meter 43 measures, for example, a phosphoric acid concentration of the processing liquid L flowing through the branch path 41. A measurement value of the concentration of the processing liquid L measured by the concentration meter 43 is outputted to the controller 5. The valve 44 controls whether or not the processing liquid L is to be supplied from the branching portion 38 to the outer tub 21b.

In the processing liquid supply system 3 of the second modification example described so far, by performing the same detection processing as in the above-described exemplary embodiment, it is possible to detect abnormality in the supply of the processing liquid L in the circulation path 32 and the branch circulation paths 32a and 32b.

Further, in the example of FIG. 9 explained so far, the circulation path 32 is branched into the two branch circulation paths 32a and 32b on its way. However, the present disclosure is not limited thereto, and the circulation path 32 may be branched into three or more branch circulation paths on its way.

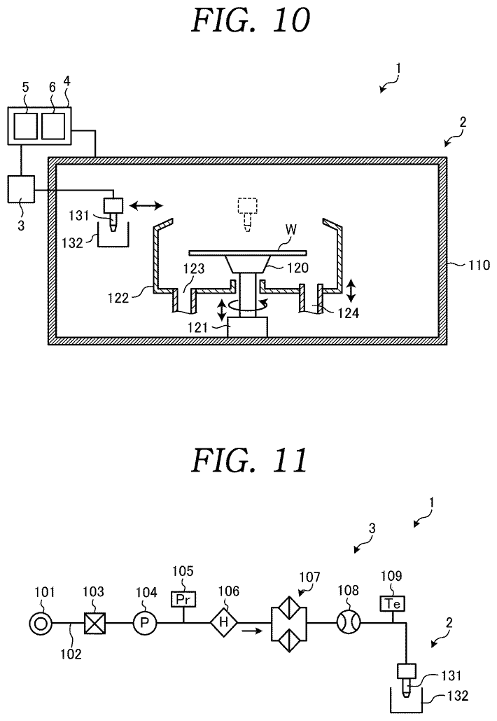

FIG. 10 is a block diagram showing a configuration example of the liquid processing device 2 according to a third modification example. As depicted in FIG. 10, the liquid processing device 2 according to the third modification example is a single-wafer processing device configured to process wafers W one by one.

The liquid processing device 2 according to the third modification example has a housing 110 whose inside is hermetically sealable. A carry-in/out opening (not shown) for carry-in/carry-out of the wafer W is formed in a side surface of the housing 110, and an opening/closing shutter (not shown) is provided at this carry-in/out opening.

A spin chuck 120 configured to hold and rotate the wafer W is provided at a central portion within the housing 110. The spin chuck 120 has a horizontal top surface, and a suction opening (not shown) for suctioning the wafer W is provided in the top surface. The wafer W can be attracted to and held on the spin chuck 120 by suctioning through this suction opening.

The spin chuck 120 is configured to be rotatable at a required speed by a chuck driver 121 such as, but not limited to, a motor. The chuck driver 121 is provided with an elevating mechanism such as a non-illustrated cylinder, and the spin chuck 120 is configured to be movable up and down by the elevating mechanism.

A cup 122 is disposed around the spin chuck 120 to collect the processing liquid L (see FIG. 3) scattered or falling from the wafer W. A drain pipe 123 for draining the collected processing liquid L and an exhaust pipe 124 for exhausting an atmosphere within the cup 122 are connected to a bottom of the cup 122.

A discharge nozzle 131 is provided at an upper portion of the housing 110. The discharge nozzle 131 is configured to be movable from a standby section 132 provided outside the top of the cup 122 to above the center of the wafer W located inside the cup 122. The discharge nozzle 131 is connected to the processing liquid supply system 3, and discharges the processing liquid L supplied from the processing liquid supply system 3 onto the wafer W.

The liquid processing device 2 and the processing liquid supply system 3 according to the third modification example are controlled by the control device 4, the same as in the above-described exemplary embodiment. The control device 4 is, for example, a computer, and includes the controller 5 and the storage 6.

FIG. 11 illustrates a configuration example of the processing liquid supply system 3 according to the third modification example. As shown in FIG. 11, the processing liquid supply system 3 according to the third modification example includes a processing liquid source 101 and a processing liquid supply path 102.

The processing liquid source 101 is, for example, a tank that stores the processing liquid L (see FIG. 3). The processing liquid supply path 102 connects the processing liquid source 101 to the discharge nozzle 131, and supplies the processing liquid L from the processing liquid source 101 to the discharge nozzle 131.

The processing liquid supply path 102 is provided with a valve 103, a pump 104, a pressure gauge 105, a heater 106, a filter 107, a flowmeter 108, and a thermometer 109 in this order from the upstream side with respect to the processing liquid source 101.

The valve 103 controls whether or not the processing liquid L is to be supplied from the processing liquid source 101 to the discharge nozzle 131. The pump 104 creates a flow of the processing liquid L that comes out of the processing liquid source 101, passes through the processing liquid supply path 102, and reaches the discharge nozzle 131.

The pump 104 is, by way of non-limiting example, a magnetic levitation pump configured to force-feed the processing liquid L as a rotator thereof is rotated in the processing liquid L while being magnetically levitated. However, the pump 104 of the present disclosure is not limited to the magnetic levitation pump, and may be a diaphragm pump or the like.

Since the magnetic levitation pump, which has higher liquid feeding capacity than other types, is used for the pump 104, the feed flow rate of the processing liquid L fed from the processing liquid supply path 102 to the discharge nozzle 131 can be increased.

The pressure gauge 105 measures the pressure of the processing liquid L flowing through the processing liquid supply path 102. A measurement value of the pressure of the processing liquid L measured by the pressure gauge 105 is outputted to the controller 5 (see FIG. 10).

The heater 106 heats the processing liquid L flowing through the processing liquid supply path 102. In the third modification example, by heating the processing liquid L with this heater 106, the processing liquid L sent to the discharge nozzle 131 is heated up to a processing temperature required for processing the wafer W.

The filter 107 removes contaminants such as particles contained in the processing liquid L flowing through the processing liquid supply path 102. The filter 107 may include multiple filter modules arranged in parallel.

The flowmeter 108 measures the flow rate of the processing liquid L flowing through the processing liquid supply path 102. A measurement value of the flow rate of the processing liquid L measured by the flowmeter 108 is outputted to the controller 5. The thermometer 109 measures the temperature of the processing liquid L flowing through the processing liquid supply path 102. A measurement value of the temperature of the processing liquid L measured by the thermometer 109 is outputted to the controller 5.

In the processing liquid supply system 3 of the third modification example described so far, by performing the same detection processing as in the above-described exemplary embodiment, it is possible to detect abnormality in the supply of the processing liquid L in the processing liquid supply path 102.

The processing liquid supply system 3 according to one or more embodiments of the present application includes a processing liquid supply path (the circulation path 32 or the processing liquid supply path 102), the pump 33 (104), the pressure gauge 34 (105), the flowmeter 39 (108), and the controller 5. The processing liquid supply path (the circulation path 32 or the processing liquid supply path 102) supplies the processing liquid L to a substrate processing device (the liquid processing device 2) configured to process a substrate (the wafer W). The pump 33 (104) is provided in the processing liquid supply path (the circulation path 32 or the processing liquid supply path 102). The pressure gauge 34 (105) and the flowmeter 39 (108) are provided downstream of the pump 33 (104) in the processing liquid supply path (the circulation path 32 or the processing liquid supply path 102). The controller 5 controls the individual components. Also, the controller 5 detects abnormality in the supply of the processing liquid L based on a measurement value of the pressure gauge 34 (105) and a measurement value of the flowmeter 39 (108). With this configuration, abnormality in the supply of the processing liquid L can be detected.

In addition, in the processing liquid supply system 3 according to one or more embodiments of the present application, the controller 5 detects abnormality in the supply of the processing liquid L when the measurement value of the flowmeter 39 (108) does not change and the measurement value of the pressure gauge 34 (105) becomes equal to or lower than the predetermined lower limit pressure P_{L}. This makes it possible to detect abnormality in the supply of the processing liquid L even when the flowmeter 39 is not outputting an appropriate measurement value due to adhesion of bubbles or the like.

Further, in the processing liquid supply system 3 according to one or more embodiments of the present application, the pump 33 (104) is a magnetic levitation pump configured to force-feed the processing liquid L as a rotator thereof is rotated in the processing liquid L while being magnetically levitated. The controller 5 performs the force-feeding of the processing liquid L while controlling the rotation speed of the rotator based on the measurement value of the flowmeter 39 (108). This makes it possible to increase the flow rate of the processing liquid L supplied to the liquid processing device 2.

In addition, in the processing liquid supply system 3 according to one or more embodiments of the present application, if there is no change in the measurement value of the flowmeter 39 (108) during the predetermined time period D2, the controller 5 detects abnormality in the supply of the processing liquid L. Thus, even when the flowmeter 39 is not outputting a proper measurement value due to adhesion of bubbles or the like, the abnormality in the supply of the processing liquid L can be detected.

Moreover, in the processing liquid supply system 3 according to one or more embodiments of the present application, the pump 33 (104) is a magnetic levitation pump configured to force-feed the processing liquid L as a rotator thereof is rotated in the processing liquid L while being magnetically levitated. In addition, if there is no change in the measurement value of the flowmeter 39 (108) during the predetermined time period D2, the controller 5 performs the force-feeding of the processing liquid L while fixing the rotation speed of the rotator to the preset rotation speed R1. This makes it possible to supply the processing liquid L to the liquid processing device 2 at a flow rate close to the processing flow rate Fₛ even in the event of a flowmeter hold phenomenon in which an appropriate flow rate feedback control cannot be carried out.

The processing liquid supply system 3 according to one or more embodiments of the present application includes a processing liquid supply path (the circulation path 32 or the processing liquid supply path 102), the pump 33 (104), the heater 36 (106), the pressure gauge 34 (105), the thermometer 45 (109), and the controller 5. The processing liquid supply path (circulation path 32 or the processing liquid supply path 102) supplies the processing liquid L to a substrate processing device (the liquid processing device 2) configured to process a substrate (the wafer W). The pump 33 (104) is provided in the processing liquid supply path (the circulation path 32 or the processing liquid supply path 102). The heater 36 (106) and the pressure gauge 34 (105) are provided downstream of the pump 33 (104) in the processing liquid supply path (the circulation path 32 or the processing liquid supply path 102). The thermometer 45 (109) measures the temperature of the processing liquid L flowing through the processing liquid supply path (the circulation path 32 or the processing liquid supply path 102). The controller 5 controls the individual components. Also, the controller 5 detects abnormality in the supply of the processing liquid L based on a measurement value of the pressure gauge 34 (105) and a measurement value of the thermometer 45 (109). With this configuration, abnormality in the supply of the processing liquid L can be detected.

The processing liquid supply system 3 according to one or more embodiments of the present application further includes the storage 6 that stores a monitoring table in which a pressure threshold according to the temperature of the processing liquid L is set. The controller 5 detects abnormality in the supply of the processing liquid L when the measurement value of the pressure gauge 34 (105) exceeds the pressure threshold according to the processing liquid L set in the monitoring table. Therefore, damage to the processing liquid supply system 3 and the liquid processing device 2 that might be caused by the abnormality in the processing liquid L can be suppressed.

The processing liquid supply system 3 according to one or more embodiments of the present application further includes the flowmeter 39 (108) provided downstream of the pump 33 (104) in the processing liquid supply path (the circulation path 32 or the processing liquid supply path 102). The pump 33 (104) is a magnetic levitation pump configured to force-feed the processing liquid L as a rotator thereof is rotated in the processing liquid L while being magnetically levitated. The controller 5 performs the force-feeding of the processing liquid L while controlling the rotation speed of the rotator based on a measurement value of the flowmeter 39 (108). Thus, the force-feed flow rate of the processing liquid L supplied to the liquid processing device 2 can be increased.

In addition, in the processing liquid supply system 3 according to one or more embodiments of the present application, when the controller 5 detects the abnormality in the supply of the processing liquid L, it stops the rotation of the rotator of the pump 33 (104) to stop the force-feeding of the processing liquid L. This makes it possible to suppress damage to the processing liquid supply system 3 and the liquid processing device 2 that might be caused by the abnormality in the supply of the processing liquid L.

### <Sequence of Control Processing>

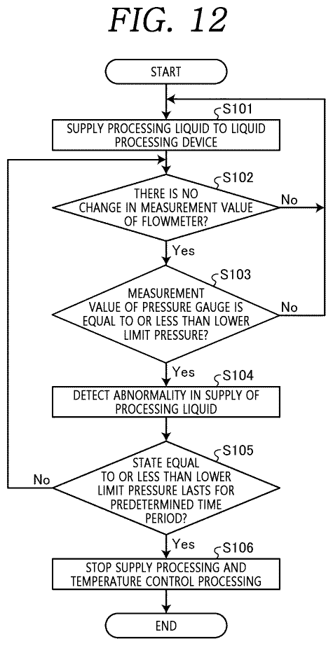

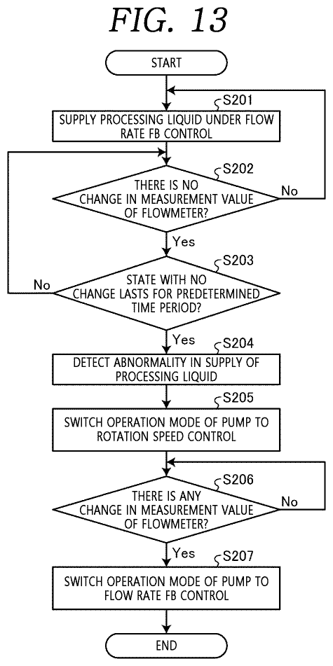

Now, a sequence of a control processing according to one or more embodiments of the present application will be explained with reference to FIG. 12 and FIG. 13. FIG. 12 is a flowchart showing an example of a sequence of a control processing performed by the processing liquid supply system 3 according to one or more embodiments of the present application.

In the control processing according to the example of FIG. 12, the controller 5 first operates the pump 33 to allow the processing liquid L to flow through the circulation path 32, thus allowing the processing liquid L to be supplied to the liquid processing device 2 (process S101).

Then, the controller 5 determines whether or not there is a change in a measurement value of the flowmeter 39 (process S102). For example, the controller 5 may make a determination that there is no change in the measurement value of the flowmeter 39 if the current measurement value of the flowmeter 39 is the same as the previous measurement value.

Then, when it is determined that there is no change in the measurement value of the flowmeter 39 (process S102, Yes), the controller 5 determines whether or not the measurement value of the pressure gauge 34 is equal to or less than the lower limit pressure P_{L} (process S103).

Then, when it is determined that the measurement value of the pressure gauge 34 is equal to or less than the lower limit pressure P_{L} (process S103, Yes), the controller 5 detects abnormality in the supply of the processing liquid L in the circulation path 32 (process S104).

Meanwhile, if it is determined that the measurement value of the pressure gauge 34 is not equal to or less than the lower limit pressure P_{L} (process S103, No), the processing returns back to the process S101. Also, if it is determined in the process S102 that there is a change in the measurement value of the flowmeter 39 (process S102, No), the processing returns back to the process S101.

Following the process S104, the controller 5 determines whether the state in which the measurement value of the pressure gauge 34 is equal to or less than the lower limit pressure P_{L} lasts for the predetermined time period D1 (process S105).

Then, when it is determined that the state in which the measurement value of the pressure gauge 34 is equal to or less than the lower limit pressure P_{L} lasts for the predetermined time period D1 (process S105, Yes), the controller 5 stops the supply processing and the temperature control processing for the processing liquid L (process S106), and ends the series of processes of the detection processing.

Meanwhile, if it is determined that the state in which the measurement value of the pressure gauge 34 is equal to or less than the lower limit pressure P_{L} does not last for the predetermined time period D1 (process S105, No), the processing returns back to the process S102.

FIG. 13 is a flowchart showing an example of a sequence of a control processing performed by the processing liquid supply system 3 according to one or more embodiments of the present application.

In the control processing according to the example of FIG. 13, the controller 5 first operates the pump 33 under a flow rate feedback control, thus allowing the processing liquid L to be supplied to the liquid processing device 2 (process S201).

Then, the controller 5 determines whether or not there is a change in the measurement value of the flowmeter 39 (process S202). By way of example, the controller 5 may make a determination that there is no change in the measurement value of the flowmeter 39 when the current measurement value of the flowmeter 39 is the same as the previous measurement value.

Then, when it is determined that there is no change in the measurement value of the flowmeter 39 (process S202, Yes), the controller 5 determines whether or not the state in which there is no change in the measurement value of the flowmeter 39 lasts for the predetermined time period D2 (process S203).

If it is determined that the state in which there is no change in the measurement value of the flowmeter 39 lasts for the predetermined time period D2 (process S203, Yes), the controller 5 detects abnormality in the supply of the processing liquid L in the circulation path 32 (process S204). Also, the controller 5 switches the operation mode of the pump 33 from the flow rate feedback control to a rotation speed control (process S205).

On the other hand, if it is determined that the state in which there is no change in the measurement value of the flowmeter 39 does not last for the predetermined time period D2 (process S203, No), the processing returns back to the process S202.

Further, if it is determined in the process S202 that there is a change in the measurement value of the flowmeter 39 (process S202, No), the processing returns back to the process S201.

Following the process S205, the controller 5 determines whether or not there is a change in the measurement value of the flowmeter 39 (process S206). Then, if it is determined that there is a change in the measurement value of the flowmeter 39 (process S206, Yes), the controller 5 switches the operation mode of the pump 33 from the rotation speed control to the flow rate feedback control (process S207), and ends the series of processes of the detection processing.

On the other hand, if it is determined that there is no change in the measurement value of the flowmeter 39 (process S206, No), the processing of the process S206 is continued.

A processing liquid supply method according to one or more embodiments of the present application includes a detection processing (process S104) of detecting abnormality in the supply of the processing liquid L based on a measurement value of the pressure gauge 34 (105) and a measurement value of the flowmeter 39 (108) in the processing liquid supply system 3. The processing liquid supply system 3 includes a processing liquid supply path (the circulation path 32 or the processing liquid supply path 102), the pump 33 (104), the pressure gauge 34 (105), and the flowmeter 39 (108). The processing liquid supply path (the circulation path 32 or the processing liquid supply path 102) supplies the processing liquid L to a substrate processing device (the liquid processing device 2) configured to process a substrate (the wafer W). The pump 33 (104) is provided in the processing liquid supply path (the circulation path 32 of the processing liquid supply path 102). The pressure gauge 34 (105) and the flowmeter 39 (108) are provided downstream of the pump 33 (104) in the processing liquid supply path (the circulation path 32 or the processing liquid supply path 102). With this configuration, abnormality in the supply of the processing liquid L can be detected.

So far, one or more embodiments of the present applications of the present disclosure has been explained. However, the present disclosure is not limited to the above-described exemplary embodiments, and various changes and modifications may be made without departing from the spirit of the present disclosure.

Here, it should be noted that the above-described exemplary embodiments are illustrative in all aspects and are not anyway limiting. The above-described exemplary embodiments may be omitted, replaced and modified in various ways without departing from the scope and the spirit of claims.

According to one or more embodiments of the present application the exemplary embodiment, it is possible to detect the abnormality in the supply of the processing liquid in the processing liquid supply path.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of one or more embodiments of the present applications. It shall be understood that all modifications and embodiments conceived from the meaning and scope of the claims and their equivalents are included in the scope of the inventive concept.

We claim:

1. A processing liquid supply system, comprising:
a processing liquid supply path through which a processing liquid is supplied to a substrate processing device configured to process a substrate;
a pump provided in the processing liquid supply path;
a pressure gauge and a flowmeter provided downstream of the pump in the processing liquid supply path; and
a controller having a processor and a memory with a computer readable program stored therein that upon execution of the computer readable program by the processor configures the controller to detect abnormality in supply of the processing liquid based on a measurement value of the pressure gauge and a measurement value of the flowmeter.

2. The processing liquid supply system of claim 1,
wherein the controller detects the abnormality in the supply of the processing liquid when there is no change in the measurement value of the flowmeter and the measurement value of the pressure gauge becomes equal to or less than a preset lower limit pressure.

3. The processing liquid supply system of claim 2,
wherein the pump is a magnetic levitation pump configured to force-feed the processing liquid as a rotator of the magnetic levitation pump is rotated in the processing liquid while being magnetically levitated, and
the controller performs force-feeding of the processing liquid while controlling a rotation speed of the rotator based on the measurement value of the flowmeter.

4. The processing liquid supply system of claim 2,
wherein the controller detects the abnormality in the supply of the processing liquid when there is no change in the measurement value of the flowmeter during a preset time period and the measurement value of the pressure gauge becomes equal to or less than a preset lower limit pressure.

5. The processing liquid supply system of claim 4,
wherein the pump is a magnetic levitation pump configured to force-feed the processing liquid as a rotator of the magnetic levitation pump is rotated in the processing liquid while being magnetically levitated, and
when there is no change in the measurement value of the flowmeter during the preset time period, the controller performs force-feeding of the processing liquid while fixing a rotation speed of the rotator to a predetermined rotation speed.

6. A processing liquid supply system, comprising:
a processing liquid supply path through which a processing liquid is supplied to a substrate processing device configured to process a substrate;
a pump provided in the processing liquid supply path;
a heater and a pressure gauge provided downstream of the pump in the processing liquid supply path;
a thermometer configured to measure a temperature of the processing liquid flowing through the processing liquid supply path; and
a controller having a processor and a memory with a computer readable program stored therein that upon execution of the computer readable program by the processor configures the controller to detect abnormality in supply of the processing liquid based on a measurement value of the pressure gauge and a measurement value of the thermometer.

7. The processing liquid supply system of claim 6, further comprising:
a storage configured to store a monitoring table in which a pressure threshold corresponding to the temperature of the processing liquid is set,
wherein the controller detects the abnormality in the supply of the processing liquid when the measurement value of the pressure gauge exceeds the pressure threshold corresponding to the temperature of the processing liquid set in the monitoring table.

8. The processing liquid supply system of claim 6, further comprising:
a flowmeter provided downstream of the pump in the processing liquid supply path,
wherein the pump is a magnetic levitation pump configured to force-feed the processing liquid as a rotator of the magnetic levitation pump is rotated in the processing liquid while being magnetically levitated, and
the controller performs force-feeding of the processing liquid while controlling a rotation speed of the rotator based on a measurement value of the flowmeter.

9. The processing liquid supply system of claim 8,
wherein when the abnormality in the supply of the processing liquid is detected, the controller stops rotation of the rotator of the pump to stop the force-feeding of the processing liquid.

10. A processing liquid supply method performed in a processing liquid supply system,
wherein the processing liquid supply system comprises:
a processing liquid supply path through which a processing liquid is supplied to a substrate processing device for processing a substrate;
a pump provided in the processing liquid supply path; and
a pressure gauge and a flowmeter provided downstream of the pump in the processing liquid supply path, and
the processing liquid supply method comprises:
detecting abnormality in supply of the processing liquid based on a measurement value of the pressure gauge and a measurement value of the flowmeter.

11. The processing liquid supply method of claim 10,
further comprising detecting the abnormality in the supply of the processing liquid when there is no change in the measurement value of the flowmeter and the measurement value of the pressure gauge becomes equal to or less than a preset lower limit pressure.

12. The processing liquid supply method of claim 11,
wherein the pump is a magnetic levitation pump configured to force-feed the processing liquid as a rotator of the magnetic levitation pump is rotated in the processing liquid while being magnetically levitated, and
the method further comprises performing force-feeding of the processing liquid while controlling a rotation speed of the rotator based on the measurement value of the flowmeter.

13. The processing liquid supply method of claim 11,
wherein the method further comprises detecting the abnormality in the supply of the processing liquid when there is no change in the measurement value of the flowmeter during a preset time period and the measurement value of the pressure gauge becomes equal to or less than a preset lower limit pressure.

14. The processing liquid supply method of claim 13,
wherein the pump is a magnetic levitation pump configured to force-feed the processing liquid as a rotator of the magnetic levitation pump is rotated in the processing liquid while being magnetically levitated, and
the method further comprises, when there is no change in the measurement value of the flowmeter during the preset time period, performing force-feeding of the processing liquid while fixing a rotation speed of the rotator to a predetermined rotation speed.

15. The processing liquid supply method of claim 10, further comprising:
measuring, by a thermometer, a temperature of the processing liquid flowing through the processing liquid supply path; and
detecting the abnormality in the supply of the processing liquid when the measurement value of the pressure gauge exceeds a pressure threshold corresponding to the temperature of the processing liquid set in a monitoring table.

16. A non-transitory computer-readable recording medium having stored thereon computer-executable instructions that, in response to execution, cause a processing liquid supply system to perform a processing liquid supply method as claimed in claim 10.

17. The non-transitory computer-readable recording medium of claim 16,
wherein the method further comprises detecting the abnormality in the supply of the processing liquid when there is no change in the measurement value of the flowmeter and the measurement value of the pressure gauge becomes equal to or less than a preset lower limit pressure.

18. The non-transitory computer-readable recording medium of claim 17,
wherein the pump is a magnetic levitation pump configured to force-feed the processing liquid as a rotator of the magnetic levitation pump is rotated in the processing liquid while being magnetically levitated, and
the method further comprises performing force-feeding of the processing liquid while controlling a rotation speed of the rotator based on the measurement value of the flowmeter.

19. The non-transitory computer-readable recording medium of claim 17,
wherein the method further comprises detecting the abnormality in the supply of the processing liquid when there is no change in the measurement value of the flowmeter during a preset time period and the measurement value of the pressure gauge becomes equal to or less than a preset lower limit pressure.

20. The computer-readable recording medium of claim 19,
wherein the pump is a magnetic levitation pump configured to force-feed the processing liquid as a rotator of the magnetic levitation pump is rotated in the processing liquid while being magnetically levitated, and
the method further comprises, when there is no change in the measurement value of the flowmeter during the preset time period, performing force-feeding of the processing liquid while fixing a rotation speed of the rotator to a predetermined rotation speed.
